(19) United States
(12) Patent Application Publication
(10) Pub. No.: US 2025/0226636 A1
(43) Pub. Date: Jul. 10, 2025

(54) OPTICAL MODULE AND METHOD FOR PRODUCING SAME

(71) Applicant: Mitsubishi Electric Corporation, Tokyo (JP)

(72) Inventor: Yutaka YONEDA, Tokyo (JP)

(73) Assignee: Mitsubishi Electric Corporation, Tokyo (JP)

(21) Appl. No.: 18/854,850

(22) PCT Filed: Apr. 28, 2022
(86) PCT No.: PCT/JP2022/019260

§ 371 Date: Oct. 7, 2024

(51) Int. Cl. H01S 5/0237; H01S 5/02315; H01S 5/042

(52) U.S. Cl. CPC H01S 5/0237; H01S 5/02315; H01S 5/04256

(57) ABSTRACT

The present disclosure includes: an optical semiconductor element having a front surface on which an electrode pad is formed; an insulating substrate having a front surface and a back surface on which respective electrode pads are formed; and an Au bump with which the electrode pad on the back surface of the insulating substrate and the electrode pad of the semiconductor element are joined to each other. The insulating substrate is disposed such that the back surface thereof faces the front surface of the semiconductor element. The electrode pad on the back surface of the insulating substrate is connected via a through-hole to the electrode pad on the front surface of the insulating substrate.

### TECHNICAL FIELD

The present disclosure relates to an optical module and a method for producing the same.

### BACKGROUND ART

An optical transceiver having a built-in optical module is a part essential to an optical communication system. Regarding this, it has been required to increase the speeds and the capacities of optical communication networks in order to accommodate data traffic that has been increasing every year. The transmission capacity can be increased by improving the mounting density and characteristics of the optical module. However, improvement of the mounting density requires technologies for decreasing the sizes of members in the optical module and mounting the members with an increased density.

Conventionally, wire bonding has been employed for assembling an optical semiconductor element. However, wire bonding involves connecting the optical semiconductor element and an insulating substrate to each other by using a wire, and thus, does not allow another member to be superposed on a surface, of either the optical semiconductor element or the insulating substrate, on which an electrode pad is formed. In addition, a backward wave is generated between the optical semiconductor element and the insulating substrate, whereby a problem arises in that characteristics significantly deteriorate.

To solve these problems, for example, Patent Document 1 discloses a technique in which joining by an ultrasonic wave is employed. This is a technique that is particularly excellent in cost, connection reliability, joining load, connection pitch accuracy, and the like in a comprehensive manner among flip chip bonding techniques that include inverting an optical semiconductor element and connecting the optical semiconductor element to an insulating substrate by using a protrusion-like terminal called a bump. In general, flip chip bonding in which joining by an ultrasonic wave is employed includes: attracting, by an attraction collet, the back surface of an optical semiconductor element having been inverted; and mounting the optical semiconductor element onto the front surface of an insulating substrate having a larger projected area than the optical semiconductor element.

### CITATION LIST

### Patent Document

Patent Document 1: Japanese Laid-Open Patent Publication No. 2012-009599 (paragraphs to [0029], FIG. 2)

### SUMMARY OF THE INVENTION

### Problem to be Solved by the Invention

However, conventional wire bonding is employed in wiring for electrical connection from the insulating substrate to an electronic circuit outside of the optical module. Consequently, a problem arises in that, separately from a region in which an electrode pad to be connected to the optical semiconductor element is formed, a region in which an electrode pad to be wire-bonded to another peripheral member is formed needs to be provided on the same surface of the insulating substrate. In addition, in order to fix the optical semiconductor element in the optical module, the optical semiconductor element needs to be joined to a member such as a sub-mount by using a solder or the like. Consequently, there is an increase in thermal stress generated owing to: preheating at the time of flip chip bonding; heat generation caused through drive of the optical semiconductor element; and a difference in linear expansion coefficient relative to the peripheral member due to cooling. Therefore, a problem arises in that the reliability of a joining portion of the bump is impaired. Furthermore, a problem arises in that, owing to pressing and vibration that occur when wire bonding is performed onto the front surface of the insulating substrate mounted over the optical semiconductor element, stress is applied to the joining portion of the bump so that the joining portion is easily broken.

The present disclosure has been made to solve the above problem, and an object of the present disclosure is to provide: an optical module that achieves decrease in size and increase in density and that ensures a high speed, a large capacity, and high reliability; and a method for producing the same.

### Means to Solve the Problem

An optical module according to the present disclosure includes: a semiconductor element having a front surface on which an electrode pad is formed; an insulating substrate having a front surface and a back surface on which respective electrode pads are formed; and a bump with which the electrode pad on the back surface of the insulating substrate and the electrode pad of the semiconductor element are joined to each other. The insulating substrate is disposed such that the back surface thereof faces the front surface of the semiconductor element. The electrode pad on the back surface of the insulating substrate is connected via a through-hole to the electrode pad on the front surface of the insulating substrate.

A method for producing an optical module according to the present disclosure includes: a step of providing a bump onto a surface of an electrode pad formed on a front surface of a semiconductor element or a surface of an electrode pad formed on a back surface of an insulating substrate, and placing the insulating substrate over the semiconductor element at such a position that the electrode pad of the semiconductor element and the electrode pad of the insulating substrate face each other; a step of heating the bump in a state where the insulating substrate is placed over the semiconductor element; and a step of joining, by an ultrasonic wave, the bump and the electrode pad of the insulating substrate or the electrode pad of the semiconductor element while pressing the bump and the electrode pad.

### Effect of the Invention

The present disclosure makes it possible to obtain an optical module that can achieve decrease in size and increase in density and that ensures a high speed, a large capacity, and high reliability.

### BRIEF DESCRIPTION OF THE DRAWINGS

FIG. 1A and FIG. 1B are cross-sectional views showing a configuration of an optical module according to embodiment 1.

FIG. 2 is an enlarged cross-sectional view showing the configuration of the optical module according to embodiment 1.

FIG. 3 is a top view showing a configuration of a conventional optical module.

FIG. 4 is a top view showing another configuration of the conventional optical module.

FIG. 5 is a top view showing the configuration of the optical module according to embodiment 1.

FIG. 6 is a top view showing a configuration of an optical module according to embodiment 2.

FIG. 7A and FIG. 7B are top views showing arrangements of bumps in optical modules other than the optical module according to embodiment 2.

FIG. 8 shows the relationship between stress and arrangement of the bumps in the optical module according to embodiment 2.

FIG. 9A to FIG. 9E are cross-sectional views showing a method for producing an optical module according to embodiment 3.

FIG. 10 is a top view showing a method for producing an optical module according to embodiment 4.

### DESCRIPTION OF EMBODIMENTS

Optical modules according to embodiments will be described below with reference to the drawings. The same or similar constituents in the drawings are denoted by the same reference characters. In order to prevent the following description from becoming unnecessarily redundant and make it easy for those skilled in the art to understand the following description, detailed description of already well-known matters and repetitive description of substantially the same configuration are sometimes omitted. The contents of the following description and the drawings are not intended to limit the subject set forth in the claims.

In the drawings, the sizes or the scales of the corresponding constituents are independent of each other. For example, the size or the scale of the same constituent sometimes differs between a drawing in which the configuration is partially changed and a drawing in which such a change is not made. In the configuration of the optical modules, more other members are provided at the time of implementation, but, in order to simplify explanations, only portions necessary for the explanations are described and explanations of the other portions are omitted.

Although the following description will be given with optical modules taken as examples, each embodiment is applicable also to, instead of optical modules, power modules and semiconductor devices that ordinarily handle current, the power modules and the semiconductor devices having similar problems.

### Embodiment 1

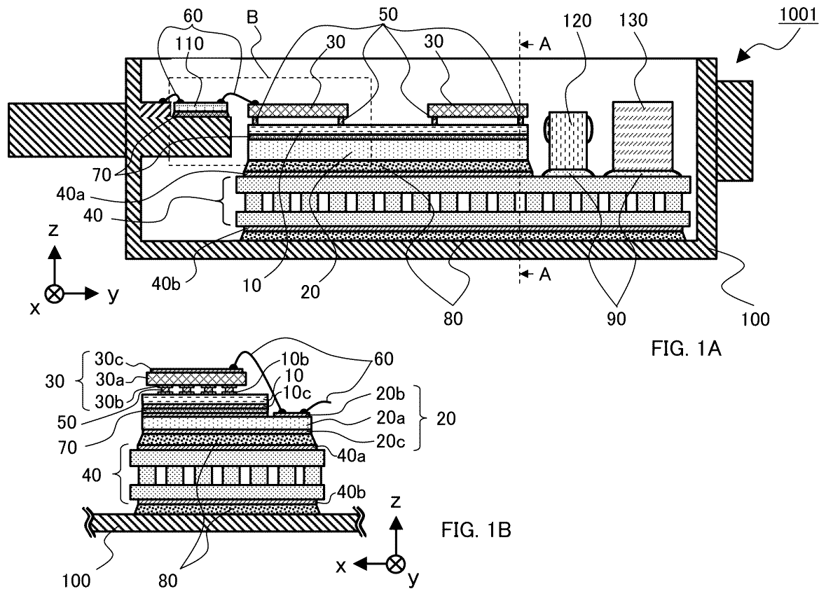

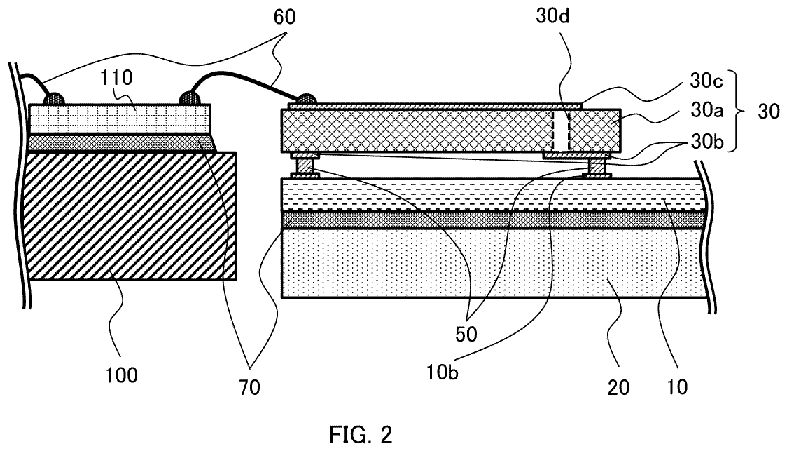

FIG. 1A and FIG. 1B are cross-sectional views showing a configuration of an optical module 1001 according to embodiment 1 of the present disclosure. FIG. 1A is a cross-sectional view of the optical module 1001, and FIG. 1B is a cross-sectional view, taken at the position A-A in FIG. 1A, of the optical module 1001 as seen in the direction of the arrows. FIG. 2 is an enlarged cross-sectional view of a region B in FIG. 1A.

As shown in FIG. 1A and FIG. 1B, the optical module 1001 has, as basic constituents, an optical semiconductor element 10, a sub-mount 20, and insulating substrates 30. The back surface of the optical semiconductor element 10 is joined to an electrode pad 20b on the front surface of the sub-mount 20 via an electrode pad 10c by using a solder 70. To the front surface of the optical semiconductor element 10 on the opposite side to the back surface thereof to which the sub-mount 20 is joined, the back surface of each of the insulating substrates 30 is joined by an ultrasonic wave via electrode pads 10b and electrode pads 30b by using Au bumps 50. The front surface of the insulating substrate 30 is provided with an Au wire 60, with an electrode pad 30c therebetween. This front surface is electrically connected to the outside via an IC 110 which is joined to a case 100 by using the solder 70.

An electrode pad 20c of the sub-mount 20 is joined to the front surface of a thermo-module 40 via a metallizing portion 40a by using an Ag paste 80. To the same front surface, of the thermo-module 40, to which the sub-mount 20 is joined, a lens 120 and a multiplexer 130 are each adhered by using a resin adhesive 90 at a position corresponding to the direction of laser output from the optical semiconductor element 10.

The thermo-module 40 is accommodated in the case 100, and the back surface of the thermo-module 40 on the opposite side to the front surface thereof provided with the sub-mount 20 and the lens 120 is adhered to the case 100 via a metallizing portion 40b by using the Ag paste 80.

More detailed description will be given below. In FIG. 1A and FIG. 1B, only basic constituents of the optical module 1001 are shown, and constituents (such as optical semiconductor elements, ICs, Au wires, capacitors, and FPCs) other than the basic constituents are not shown.

The optical semiconductor element 10 converts an electrical signal into an optical signal or converts an optical signal into an electrical signal. The optical semiconductor element 10 can be implemented by, for example, a laser diode (LD), a photodiode (PD), or the like. The optical semiconductor element 10 is made from, for example, InP, GaAs, GaN, InGaAs, Ge, Si, or the like. In the present embodiment 1, a Mach-Zehnder modulator (hereinafter, MZ modulator) made from InP is used. The number of laser light generation units of the optical semiconductor element 10 is not limited. In the present embodiment 1, a plurality of laser light generation units are formed, and, with such a plurality of laser light generation units, the advantageous effect of the present disclosure is more prominently exhibited.

The optical semiconductor element 10 is electrically and mechanically joined to the insulating substrate 30 by using the Au bumps 50, and thus a dummy pad for mechanically fixing the insulating substrate 30 and each of the electrode pads 10b electrically connectable to the insulating substrate 30, is formed through metallization with Au.

In the present embodiment 1, the number of the MZ modulators mounted in the optical module 1001 is one. However, other optical semiconductor elements that are unnecessary for explaining the present disclosure and thus are not described, are also mounted in the optical module 1001. Thus, the number of the optical semiconductor elements 10 is not limited to one.

As shown in FIG. 1B, the sub-mount 20 has: a ceramic base material 20a; electrode pads 20b formed on the front surface of the ceramic base material 20a; and the electrode pad 20c formed on the back surface of the ceramic base material 20a. The ceramic base material 20a is an electrically insulating material. As the ceramic base material 20a, in order to effectively cool the optical semiconductor element 10, a material having a high thermal conductivity is preferable, and in general, a ceramic sheet made from AlN, Al₂O₃, or the like is used, for example.

In the present embodiment 1, the number of the sub-mounts 20 mounted in the optical module 1001 is one. However, the number of the sub-mounts 20 is not limited to one. A plurality of the optical semiconductor elements may be joined to one sub-mount.

In general, the electrode pads 20b and 20c are made from the same material. By using the solder 70, the optical semiconductor element 10 is soldered to the corresponding electrode pad 20b, on the front surface, that is formed on the circuit surface side. Another one of the electrode pads 20b is electrically connected to a peripheral member and the front surface of the optical semiconductor element 10 through formation of joining portions by using Au wires 60 or the like. Such an electrode pad 20b is a wiring member for electrically connecting the optical semiconductor element 10 and an external circuit to each other, and thus, is preferably made from a metal having a low electrical resistance.

In general, as each of the electrode pads 20b and 20c, a metallizing portion made from Au or the like and having a thickness of about 3.0 μm or smaller is used, for example. In the present embodiment 1, the following sub-mount 20 is used. That is, a ceramic base material 20a made from AlN and having a thickness of 0.5 mm is metallized with electrode pads 20b which are each made from Au and which each have a thickness of 1.0 μm, and the electrode pad 20b at the location to which the optical semiconductor element 10 is to be soldered is pre-coated with an AuSn solder 70 having a thickness of 5 μm.

The electrode pad 20c on the back surface corresponding to a heat dissipation surface side is mechanically and thermally connected to the inner wall of the case 100 via a solder, an Ag paste, or the like. In the present embodiment 1, the connection is made by using the Ag paste 80.

Similar to the sub-mount 20, as shown in FIG. 2, the insulating substrate 30 has: a ceramic base material 30a; the electrode pads 30b formed on the back surface of the ceramic base material 30a; and the electrode pad 30c formed on the front surface of the ceramic base material 30a. The ceramic base material 30a is an electrically insulating material. As the ceramic base material 30a, in general, a ceramic sheet made from AlN, Al₂O₃, or the like is used. In the present embodiment 1, the insulating substrates 30 mounted in the optical module 1001 are each joined by an ultrasonic wave to the optical semiconductor element 10 by using the Au bumps 50. The number of the insulating substrates 30 is not limited and may be one or more.

In general, the electrode pads 30b and the electrode pad 30c are made from the same material. Each of the electrode pads 30b formed on the back surface of the ceramic base material 30a is joined to the corresponding electrode pad 10b on the front surface of the optical semiconductor element 10 by using the corresponding Au bump 50, and the electrode pad 30b joined to the optical semiconductor element 10 is electrically connected via a through-hole 30d, a side-surface metallizing portion, and the like to the electrode pad 30c on the front surface of the ceramic base material 30a. The electrode pad 30c electrically connected to the electrode pad 30b is further electrically connected to a peripheral member through formation of a joining portion by using the Au wire 60 or the like. Such electrode pads 30b and 30c are wiring members for electrically connecting the optical semiconductor element 10 and the external circuit to each other, and thus, are each preferably made from a metal having a low electrical resistance.

In general, as each of the electrode pads 30b and 30c, a metallizing portion made from Au or the like and having a thickness of about 3.0 μm or smaller is used, for example. In the present embodiment 1, a ceramic base material 30a made from AlN and having a thickness of 0.25 mm is metallized with electrode pads 30b and 30c which are each made from Au and which each have a thickness of 1.0 μm, and the electrode pads 30b and 30c are electrically connected to each other via the through-hole 30d provided in the ceramic base material 30a. Furthermore, the electrode pad 30c is electrically connected to the IC 110 by using the Au wire 60.

The thermo-module 40 transmits heat received by a heat absorption unit to a heat dissipation unit via a Peltier element and dissipates the heat from the heat dissipation unit to, for example, the case 100. In this manner, the temperature of the optical semiconductor element 10 is controlled by the thermo-module 40. Consequently, the optical semiconductor element 10 can continue stable operation.

As shown in FIG. 1A and FIG. 1B, the thermo-module 40 is adhered to the case 100 by using the Ag paste 80 such that a main surface, of the thermo-module 40, to which the sub-mount 20 is joined is oriented in a positive direction of a Z axis. Therefore, the thermo-module 40 has: an adhesion surface, for adhesion to the sub-mount 20, the lens 120, and the multiplexer 130, on which the metallizing portion 40a is formed; and an adhesion surface, for adhesion to the case 100 via the Ag paste 80, on which the metallizing portion 40b is formed.

In general, the metallizing portions 40a and 40b are made from the same material. As each of the metallizing portions 40a and 40b, a metallizing portion made from Au or the like and having a thickness of about 3.0 μm or smaller is used, for example.

By using the Au bumps 50, the respective electrode pads 10b and dummy pads (not shown) formed on the front surface of the optical semiconductor element 10 and the respective electrode pads 30b formed on the back surface of the insulating substrate 30 are electrically and mechanically connected to each other or mechanically connected to each other. A material of the Au bumps 50 is preferably a metal having a high thermal conductivity. Therefore, in general, Au, Cu, Al, a solder, and the like are used singly or in combination, and the metal is joined by means such as heating, pressing, an ultrasonic wave, or soldering.

In the present embodiment 1, stud bumps are joined by an ultrasonic wave to the electrode pads 10b and the dummy pads of the optical semiconductor element 10. The stud bumps are formed on the respective electrode pads 30b formed on the insulating substrate 30. The stud bumps are formed by performing first bonding of wire bonding (ball bonding) with Au and then cutting the wires. Au wires each having a diameter φ of 25 μm are used such that the bumps each have a size φ of about 45 μm, and the height thereof to the tip is about 45 um.

Each of the Au wires 60 makes electrical connection between: the electrode pad 30c formed on the front surface of the insulating substrate 30; and the IC 110, the corresponding electrode pad 20b formed on the front surface of the sub-mount 20, or the like. A material of the Au wire 60 is preferably a metal having a low electrical resistance. Therefore, in general, Au, Cu, Al, and the like are used singly or in combination, and the metal is joined mainly by an ultrasonic wave.

In FIG. 1A and FIG. 1B regarding the present embodiment 1, the electrode pad 30c formed on the insulating substrate 30 and the IC 110 are joined to each other and the IC 110 and the case 100 are joined to each other, through wire bonding (ball bonding) with Au. However, since Au wires 60 are used also for connection between other members that are unnecessary for explaining the present disclosure and thus are not described, the number of the locations of the Au wires 60 according to specifications is not limited to two.

By using the solder 70, the corresponding electrode pad 20b formed on the front surface of the sub-mount 20 and the electrode pad 10c formed on the back surface of the optical semiconductor element 10 are joined to each other. The optical semiconductor element 10 is joined to the sub-mount 20 by using the solder 70 before the sub-mount 20 is adhered to the thermo-module 40 by using the Ag paste 80. Considering this, a material of the solder 70 is preferably a metal that has a high thermal conductivity and that has a melting point higher than the curing temperature of the Ag paste 80 such that the solder 70 is not melted again while joining is being performed by using the Ag paste 80. Therefore, in general, an alloy that contains Sn, Pb, Au, Ag, Cu, Zn, Ni, Sb, Bi, In, Ge, etc., and that has a melting point of lower than 450° C., is used as the solder 70. As such an alloy, it is preferable to use an alloy that mainly contains Sn, Au, Ag, Cu, etc., and that has a melting point of 200° C. or higher. The solder 70 preferably has a thickness of 0.1 mm or smaller from the viewpoint of the tilt and the warping of the element. In the present embodiment 1, a eutectic solder of Sn and Au is used.

By using the Ag paste 80, the electrode pad 20c formed on the back surface of the sub-mount 20 and the metallizing portion 40a formed on the front surface of the thermo-module 40 are adhered to each other, and the metallizing portion 40b formed on the back surface of the thermo-module 40 and the case 100 are adhered to each other. The sub-mount 20 is adhered to the thermo-module 40 by using the Ag paste 80 after the optical semiconductor element 10 is joined to the sub-mount 20 by using the solder 70. Considering this, a material of the Ag paste 80 desirably has a high thermal conductivity and desirably has a curing temperature lower than the melting point of the solder 70 such that the solder 70 is not melted again while adhesion is being performed by using the Ag paste 80. Therefore, in general, an electrically conductive adhesive in which an electrically conductive filler obtained by setting the shape of a metal such as Au, Ag, or Cu to a spherical shape or a flake shape has been blended with an organic binder such as an epoxy-based binder or a phenol-based binder, is used as the Ag paste 80. Alternatively, joining by using a metal material such as a solder or a sintered material may be performed or an insulative adhesive containing no metal may be used as long as the metal material or the insulative adhesive has a high thermal conductivity and allows adhesion or joining to be performed at a temperature at which the solder 70 is not melted again. In the present embodiment 1, an Ag paste 80 in which Ag particles having flake shapes have been blended with an epoxy-based binder is used.

By using the resin adhesive 90, the lens 120 and the metallizing portion 40a formed on the front surface of the thermo-module 40 are adhered to each other, and the multiplexer 130 and the metallizing portion 40a are adhered to each other. Each of these members is adhered by using the resin adhesive 90 after the optical semiconductor element 10 has been joined to the sub-mount 20 by using the solder 70. Considering this, a material of the resin adhesive 90 desirably has a curing temperature lower than the melting point of the solder 70 such that the solder 70 is not melted again while adhesion is being performed by using the resin adhesive 90. In addition, the material desirably has such a viscosity as not to allow the material to be wet and spread to the surrounding and desirably has such a tackiness as not to allow movement of the lens 120 and the multiplexer 130 having been mounted. The material is more preferably a resin that can be cured and adhered by means other than heating, such as radiation of ultraviolet rays. In the present embodiment 1, the interval between the metallizing portion 40a and the lens 120 to be adhered to each other by using the resin adhesive 90 and the interval between the metallizing portion 40a and the multiplexer 130 to be adhered to each other by using the resin adhesive 90 are not conduction paths, and thus the resin adhesive 90 does not have to be electrically conductive.

The case 100 is a flat box having: a bottom portion which has the shape of a flat plate and to which the metallizing portion 40b formed on the back surface of the thermo-module 40 is adhered by using the Ag paste 80; a plurality of side portions each contiguous with the corresponding outer edge of the bottom portion; and an opening portion enclosed by the plurality of side portions. As shown in FIG. 1A and FIG. 1B, one of the side portions of the case 100 is provided with a sending-out unit for guiding, to an optical fiber (not shown), laser light having been multiplexed through combination by the multiplexer 130.

The lens 120 is formed of glass or transparent resin and condenses laser light sent out from the optical semiconductor element 10. In the present embodiment 1, only one lens 120 is shown. However, a plurality of the lenses 120 are arranged in the depth direction in FIG. 1A and FIG. 1B according to the number of light sources of the optical semiconductor element 10. Thus, the number of the lenses 120 is not limited to one.

The multiplexer 130 combines lights sent out from the optical semiconductor element 10 and outputs the resultant combination light. The combination light outputted from the multiplexer 130 is transmitted as a multiplexed signal in an optical waveguide such as the optical fiber through the lens 120 provided in the case 100.

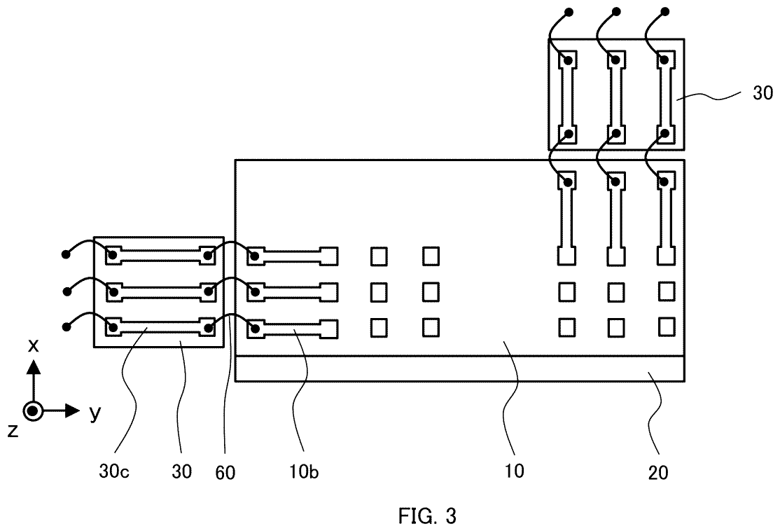

FIG. 3 is a top view showing a configuration of a conventional optical module. The conventional optical module includes a plurality of the optical semiconductor elements 10 in order to increase transmission capacity, and there are many parts that should be mounted, such as lenses and multiplexers. However, the outer dimension of the case of the optical module is predetermined, and thus high-density mounting technologies are required for mounting all of the mounting parts into the case.

In the conventional optical module, wire bonding in which Au wires 60 are used is employed for connection between each of the optical semiconductor elements 10, the corresponding sub-mount 20, and the corresponding insulating substrates 30. However, in wire bonding, it is difficult to superpose the members, and in addition, a backward wave is generated between the optical semiconductor element 10 and the insulating substrates 30, and thus there is a concern that characteristics significantly deteriorate.

In order to superpose the members while improving the characteristics by preventing generation of such a backward wave, joining by an ultrasonic wave is employed. The joining by an ultrasonic wave is a technique that is particularly excellent in cost, connection reliability, joining load, connection pitch accuracy, and the like in a comprehensive manner among flip chip bonding techniques that include connecting, by using the Au bumps 50, the insulating substrates 30 and the optical semiconductor element 10 having been inverted.

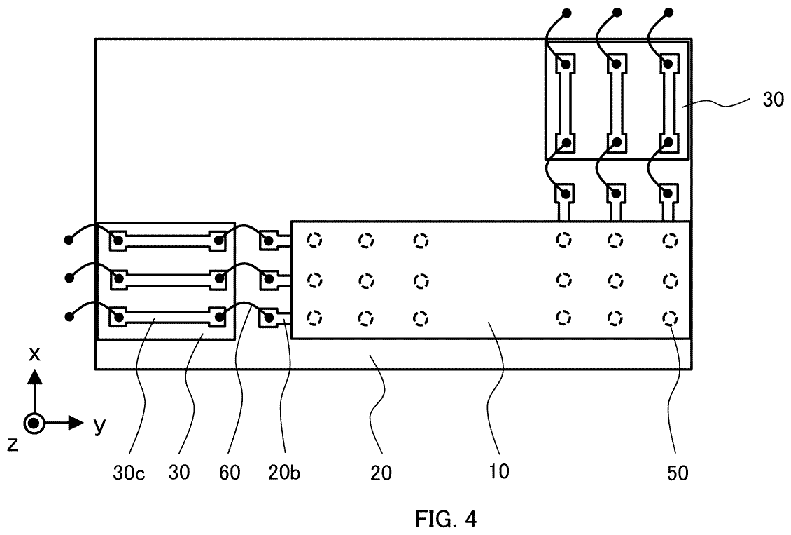

FIG. 4 is a top view showing a configuration of the conventional optical module obtained through a flip chip bonding technique in which joining by an ultrasonic wave is employed. In general, flip chip bonding in which joining by an ultrasonic wave is employed includes: attracting, by a collet, the back surface of the optical semiconductor element 10 having been inverted; and mounting the optical semiconductor element 10 onto the front surface of the sub-mount 20 having a larger projected area than the optical semiconductor element 10. However, conventional wire bonding in which the Au wires 60 are used is employed as usual in, for example, wiring to feedthroughs or the like for electrical connection from the sub-mount 20 and the insulating substrates 30 to an external electronic circuit provided to the case.

Considering this, it is necessary that, separately from electrode pads 20b connected to the optical semiconductor element 10, electrode pads 20b for wire bonding to another peripheral member are formed on the same surface of the sub-mount 20. The latter electrode pads 20b have to be formed outside of the projected area of the optical semiconductor element 10. As a result, the area of the sub-mount 20 needs to be larger than the area of the optical semiconductor element 10 at least by the area of the electrode pads 20b for wire bonding to the other member. In addition, no other members can be mounted within the back surface of the optical semiconductor element 10 having been inverted, i.e., within the surface of the optical semiconductor element 10 shown in FIG. 4.

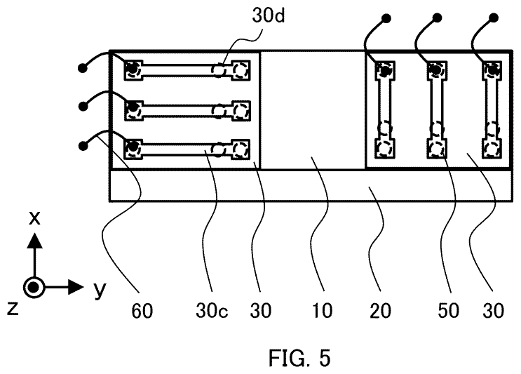

FIG. 5 is a top view showing a configuration of a basic constituent part of the optical module according to embodiment 1 of the present disclosure. As shown in FIG. 5 and FIG. 2, the basic constituent part of the optical module 1001 is provided with the insulating substrates 30 having both surfaces on which electrode pads 30b and 30c electrically connected to each other via the through-holes 30d are formed.

With this configuration, in the same manner as in conventional flip chip bonding, the electrode pads for mounting through wire bonding are eliminated from the optical semiconductor element 10, whereby the size of the optical semiconductor element 10 can be decreased. Moreover, each of the insulating substrates 30 smaller than the optical semiconductor element 10 is mounted over the optical semiconductor element 10, and thus all of the optical semiconductor element 10 and the insulating substrate 30 which can be mounted only in the XY directions shown in FIG. 3 and FIG. 4 in the conventional method, are mounted in the Z direction, whereby the members can be mounted with a high density. Along with these advantages, the electrode pad 30c for wire bonding to another peripheral member can be formed on the front surface of the insulating substrate 30 mounted over the optical semiconductor element 10, whereby the density of the members can be increased and the sizes of the members can be decreased as compared to the case of the conventional flip chip bonding. In addition, the front surface of the insulating substrate 30 having a smaller projected area than the optical semiconductor element 10 can be attracted by a collet, and the insulating substrate 30 can be mounted over the front surface of the optical semiconductor element 10.

As described above, the optical module 1001 according to the present embodiment 1 includes: an optical semiconductor element 10 having a front surface on which an electrode pad 10b is formed; an insulating substrate 30 having a front surface and a back surface on which respective electrode pads 30c and 30b are formed; and an Au bump 50 with which the electrode pad 30b on the back surface of the insulating substrate 30 and the electrode pad 10b of the semiconductor element 10 are joined to each other. The insulating substrate 30 is disposed such that the back surface thereof faces the front surface of the semiconductor element 10. The electrode pad 30b on the back surface of the insulating substrate 30 is connected via a through-hole 30d to the electrode pad 30c on the front surface of the insulating substrate 30. Consequently, electrode pads for mounting through wire bonding are eliminated from the optical semiconductor element, whereby the size of the optical semiconductor element can be decreased. Furthermore, since the optical semiconductor element and the insulating substrate are electrically and mechanically joined to each other not through the conventional wire bonding in which Au wires are used, but by using the Au bumps, frequency characteristics can be improved as compared to a case where the joining is performed through wire bonding. In addition, since the insulating substrate is mounted in the thickness direction of the optical semiconductor element, a smaller area is necessary for mounting the optical semiconductor element, the sub-mount, and the insulating substrate, and the density of the optical module can be increased. Therefore, an optical module that ensures a higher speed and a larger capacity than in the conventional configuration can be obtained.

### Embodiment 2

In embodiment 1, the Au bumps 50 are evenly arranged within a surface of the insulating substrate 30. Meanwhile, in embodiment 2, description will be given regarding a case where the Au bumps 50 are arranged at both ends of the insulating substrate 30.

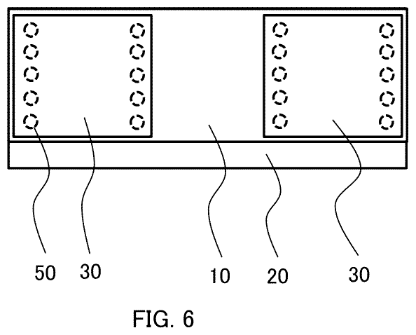

FIG. 6 is a top view showing a configuration of an optical module 1001 according to embodiment 2 of the present disclosure. As shown in FIG. 6, in the optical module 1001 according to embodiment 2, the Au bumps 50 are arranged in a concentrated manner along both end sides of the insulating substrate 30.

The optical module 1001 according to the present embodiment 2 has the same basic configuration as that of the optical module 1001 according to embodiment 1 but differs only in terms of the arrangement of the Au bumps 50 shown in FIG. 6. Therefore, here, the difference will be mainly described, and description of the same constituents will be omitted. FIG. 6 shows only the optical semiconductor element 10, the sub-mount 20, the insulating substrates 30, and the Au bumps 50 in the optical module 1001 according to embodiment 2 and does not explain the other constituents.

In the optical modules 1001 according to embodiment 1 and embodiment 2, thermal stress is generated owing to: heating when the sub-mount 20 is joined by using the solder 70; preheating at the time of flip chip bonding; and heat generation caused through drive of the optical semiconductor element 10. In addition, thermal stress might be generated owing to a difference in linear expansion coefficient relative to a peripheral member due to cooling. Conceivable methods for decreasing such thermal stress to be applied to joining portions of the Au bumps 50 are: a method that includes increasing the number of the Au bumps 50; a method that includes evenly arranging the Au bumps 50 within the surface of each of the insulating substrates 30 as described in embodiment 1; and the like.

In a case where a plurality of laser light generation units are formed in the optical semiconductor element 10 in order to increase the capacity of the optical module 1001, a plurality of laser lights outputted from the optical semiconductor element 10 are condensed by the lenses 120 and combined by the multiplexer 130 as shown in FIG. 1A and FIG. 1B. Therefore, in order to stably output the resultant combination light, the electrode pads 10b formed on the optical semiconductor element 10 are preferably positioned so as to be arrayed in one row with respect to each of the laser light generation units as shown in FIG. 6.

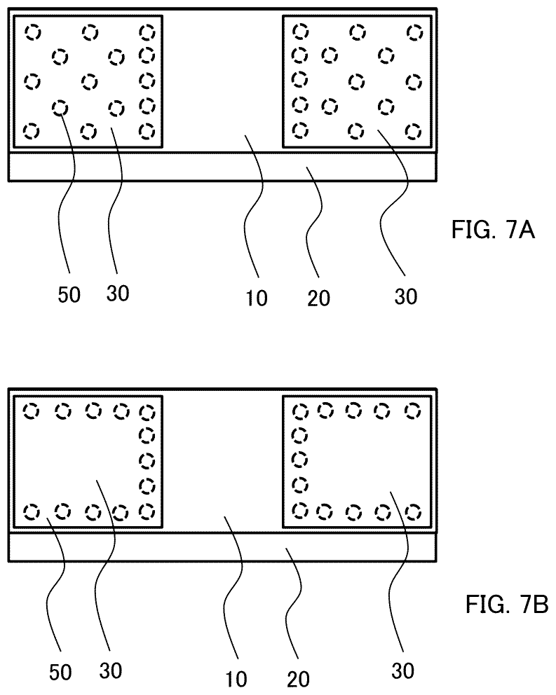

FIG. 7A and FIG. 7B are top views showing other arrangements of the bumps in optical modules. In a case where a plurality of laser light generation units are formed on one said optical semiconductor element 10 in order to increase the capacity of the optical module 1001, the following configuration is employed in order to enable stable output of combination light and evenly arrange, within the surface of the insulating substrate 30, dummy electrodes for mechanically fixing the insulating substrate 30 to the optical semiconductor element 10. That is, the electrodes within the surface of the insulating substrate 30 are such that, as shown in FIG. 7A, Au bumps 50 at the end on one side of the insulating substrate 30 are arranged in one row and the other Au bumps 50 are evenly arranged within the surface of the insulating substrate 30, for example.

However, such arrangement of the Au bumps 50 leads to the following concern. That is, when thermal stress has been applied to the joining portions of the Au bumps 50, there is unevenness in the thermal stress applied to the joining portions of the Au bumps 50 arranged within the surface of the insulating substrate 30, whereby the joining portion of any of the Au bumps 50 to which the thermal stress is most strongly applied easily peels.

As a countermeasure, it is possible to increase the number of the Au bumps 50. However, the load required for flip chip bonding is also increased according to the increased number of the Au bumps 50. Consequently, in the configuration of the present embodiment 2, since vibration is generated between the surface of the attraction collet and the electrode pads 30c on the front surface of the insulating substrate 30, the increase in the load might lead to problems such as a problem that any of the electrode pads 30c is deformed so as to come into contact with an adjacent one of the electrode pads 30c, whereby short-circuiting occurs therebetween. In addition, the number of the dummy electrode pads 10b necessary on the optical semiconductor element 10 increases according to the increased number of the Au bumps 50, whereby the size of the optical semiconductor element 10 is increased.

Considering this, the present embodiment 2 employs the arrangement shown in FIG. 6. That is, the Au bumps 50 are arranged in a concentrated manner on both end sides of the insulating substrate 30 as means for enabling stable output of combination light with respect to the plurality of laser light generation units on the optical semiconductor element 10 and evenly dispersing stress applied to the joining portions of the Au bumps 50 in a state where the size of the optical semiconductor element 10 is decreased without increasing the number of the dummy pads, to ensure reliability required of the product.

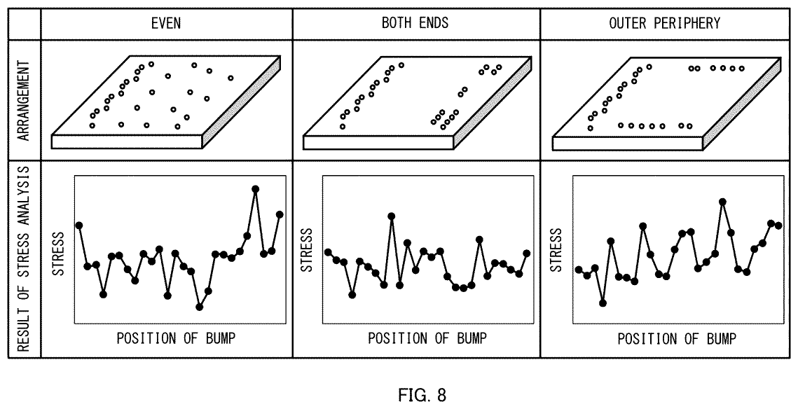

Consequently, increase of the thermal stress to be applied to the joining portion of a specific one of the Au bumps 50 at the time of cooling subsequent to flip chip bonding can be suppressed as compared to a case where the Au bumps 50 are evenly arranged within the substrate as shown in FIG. 7A and a case where the Au bumps 50 are arranged along the outer periphery of the substrate as shown in FIG. 7B. FIG. 8 shows the results of stress analysis regarding the arrangement of the bumps in the optical module according to embodiment 2 and the other arrangements of the bumps.

Regarding the number and the arrangement of the Au bumps 50, in a case where the electrode pads 10b are formed in one row with respect to each of the plurality of laser light generation units formed on the optical semiconductor element 10 as in the present embodiment 2, arrangement of the Au bumps 50 at other positions on the insulating substrate 30 poses no problem as long as the Au bumps 50 are arranged so as to face both ends of the insulating substrate 30. However, when the number of the Au bumps 50 is increased, the increase might lead to the above problems such as: the problem that short-circuiting between the electrode pads 30c formed on the insulating substrate 30 occurs at the time of flip chip bonding; and the problem that the size of the optical semiconductor element 10 is increased. Therefore, the Au bumps 50 are preferably arranged on opposed sides as dummy electrodes, the number of which is approximately equal to the number of the electrode pads 10b arranged in one row according to the number of the laser light generation units formed on the optical semiconductor element 10.

In addition, as shown in FIG. 1A and FIG. 1B, the insulating substrate 30 mounted over the optical semiconductor element 10 is connected from any of the electrode pads 30c formed on the front surface thereof to the IC 110 or the like by using the corresponding Au wire 60. In this case, the electrode pad 30c for bonding of the Au wire 60 is preferably formed at an end of the insulating substrate 30 in order to shorten the Au wire 60. Since this Au wire 60 is subjected to wire bonding after the insulating substrate 30 is mounted over the optical semiconductor element 10, stress is applied to the joining portions of the Au bumps 50 owing to pressing with a tool at the time of the wire bonding. Thus, by arranging the Au bumps 50 in a concentrated manner on both end sides of the insulating substrate 30 as in the present embodiment 2, the joining portion of a specific one of the Au bumps 50 can be inhibited from peeling owing to application of stress to the joining portion at the time of wire bonding onto the electrode pad 30c of the insulating substrate 30.

As described above, the optical module 1001 according to the present embodiment 2 includes: an optical semiconductor element 10 having a front surface on which an electrode pad 10b is formed; an insulating substrate 30 having a front surface and a back surface on which respective electrode pads 30c and 30b are formed; and an Au bump 50 with which the electrode pad 30b on the back surface of the insulating substrate 30 and the electrode pad 10b of the semiconductor element 10 are joined to each other. The insulating substrate 30 is disposed such that the back surface thereof faces the front surface of the semiconductor element 10. The electrode pad 30b on the back surface of the insulating substrate 30 is connected via a through-hole 30d to the electrode pad 30c on the front surface of the insulating substrate 30. The Au bump 50 is located at each of a position close to one end of the insulating substrate 30 and a position close to another end, of the insulating substrate 30, opposite to the one end. Consequently, as compared to a case where the Au bumps are evenly arranged within the surface of the insulating substrate and a case where the Au bumps are arranged along the entire outer periphery of the insulating substrate, the joining portion of a specific one of the Au bumps can be inhibited from peeling owing to increase, at the joining portion, in: thermal stress applied at the time of cooling subsequent to flip chip bonding; and stress applied at the time of wire bonding onto the electrode pad of the insulating substrate subsequent to the flip chip bonding. Therefore, the yield and the reliability of the optical module can be improved. In addition, no Au bump has to be disposed at a center portion of the insulating substrate, and accordingly, the number of the Au bumps necessary for ensuring the reliability of the product can be decreased, whereby the load necessary for flip chip bonding can be decreased. Consequently, any of the electrode pads on the front surface of the insulating substrate can be inhibited from, owing to friction with the tip of an attraction collet caused by vibration due to an ultrasonic wave, being deformed so as to come into contact with an adjacent one of the electrode pads, whereby short-circuiting due to the contact can be inhibited. In addition, since the number of the necessary Au bumps can be decreased, the number of the dummy electrode pads that are formed on the optical semiconductor element and that are for merely mechanically fixing the insulating substrate can also be decreased. Accordingly, the size of the optical semiconductor element can be further decreased. Therefore, an optical module that is less expensive and that has a higher yield and higher reliability can be obtained.

### Embodiment 3

In embodiment 3, a method for producing the optical semiconductor element 10, the sub-mount 20, and each of the insulating substrates 30 of the optical module 1001 according to embodiment 1 will be described.

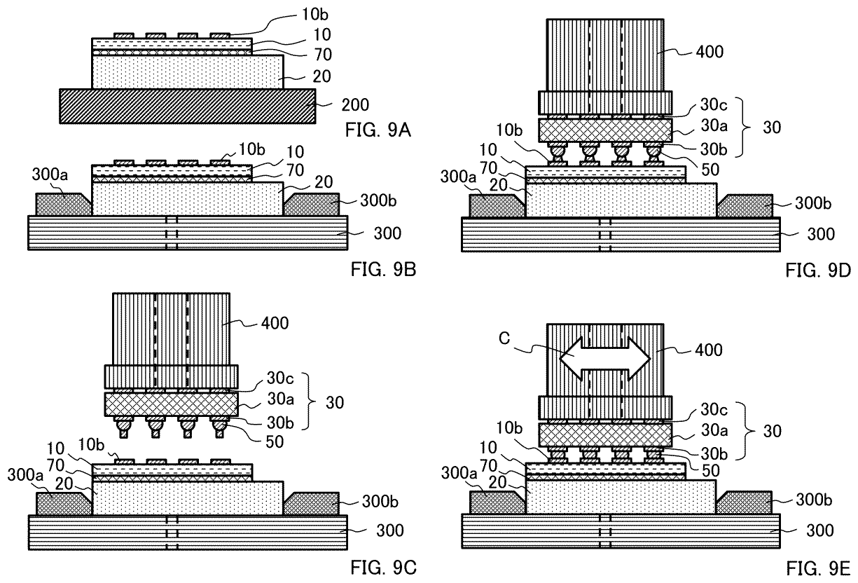

FIG. 9A to FIG. 9E are cross-sectional views showing the method for producing the optical module according to embodiment 3. FIG. 9A to FIG. 9E show only a method including steps of producing the optical semiconductor element 10, the sub-mount 20, and the insulating substrate 30 of the optical module 1001 according to embodiment 3. FIG. 9A to FIG. 9E do not show other steps since the other steps are the same as those for conventional optical modules. The other steps include other assembling steps for the optical module 1001 such as: a step of fixing the thermo-module 40 to the case 100; a step of mounting, onto the thermo-module 40 fixed to the case 100, the optical semiconductor element 10, the sub-mount 20, and the insulating substrate 30 which have been assembled; a step of performing wire bonding onto the IC 110 from the electrode pad 30c of the insulating substrate 30 mounted over the thermo-module 40; and a step of mounting the lens 120 and the multiplexer 130 between the sending-out unit of the case 100 and the laser light generation units formed on the optical semiconductor element 10.

First, as shown in FIG. 9A, the sub-mount 20 is placed on a hot plate 200 heated to 280° C., which is the melting point of the AuSn solder 70 pre-coating the corresponding electrode pad 20b of the sub-mount 20, or higher. Consequently, the AuSn solder 70 is melted, whereby the sub-mount 20 is soldered to the optical semiconductor element 10.

At this time, the timing of placing the optical semiconductor element 10 onto the sub-mount 20 may be: after it is confirmed that the AuSn solder 70 has been melted; or before the AuSn solder 70 has been melted. However, in order to decrease the size of the sub-mount 20, the dimension of the pre-coating AuSn solder 70 is preferably set to be approximately equal to that of the optical semiconductor element 10, and thus, when the dimension of the pre-coating AuSn solder 70 is not larger than that of the optical semiconductor element 10, the optical semiconductor element 10 is preferably placed after it is confirmed that the AuSn solder 70 has been melted. In the present embodiment 3, the heating temperature of the hot plate 200 is set to 340° C.

Next, as shown in FIG. 9B, the sub-mount 20 to which the optical semiconductor element 10 has been die-bonded is placed on a stage 300 of an ultrasonic mounting machine. Before this placement, the stage 300 of the ultrasonic mounting machine has been preheated to 200° C. which is a temperature lower than the melting point of the AuSn solder 70, in order to improve the joining performances of the Au bumps 50. The sub-mount 20 placed on the stage 300 is attracted onto the stage 300 by vacuum, and side surfaces on both sides, in a direction of application of vibration due to an ultrasonic wave, of the sub-mount 20 are mechanically sandwiched by using jigs 300a and 300b. Consequently, the sub-mount 20 is fixed so as not to be moved in the direction of vibration due to an ultrasonic wave.

Furthermore, as shown in FIG. 9C, the Au bumps 50 are formed in advance at positions, on the electrode pads 30b of the insulating substrate 30, that correspond to the positions of the electrode pads 10b on the optical semiconductor element 10, a surface, of the insulating substrate 30, on which the electrode pad 30c has been formed is attracted by an attraction collet 400 of the ultrasonic mounting machine, and the insulating substrate 30 is transported to a predetermined position above the optical semiconductor element 10 preheated to 200° C. The insulating substrate 30 is placed over the optical semiconductor element 10 such that the electrode pads 30b, of the insulating substrate 30, on which the Au bumps 50 have been formed and the respective electrode pads 10b, of the optical semiconductor element 10, which correspond to the electrode pads 30b are positioned so as to face each other. Although the Au bumps 50 are formed on the electrode pads 30b in the present embodiment 3, the Au bumps 50 may be formed in advance on the electrode pads 10b of the optical semiconductor element 10.

Thereafter, as shown in FIG. 9D, the insulating substrate 30 attracted by the attraction collet 400 is pressed in a state of being placed over the optical semiconductor element 10. A common step performed at this time is a step of applying vibration due to an ultrasonic wave immediately after the pressing, to join the optical semiconductor element 10 and the Au bumps 50 to each other. Meanwhile, in the present embodiment 3, the Au bumps 50 are also heated to 200° C. which is approximately equal to the temperature of the optical semiconductor element 10 by, for example, preheating the attraction collet 400 or continuing to press the insulating substrate 30 against the optical semiconductor element 10 via the Au bumps 50.

Lastly, as shown in FIG. 9E, in a state where the Au bumps 50 are heated to about 200° C. similarly to the optical semiconductor element 10, vibration due to an ultrasonic wave is applied, by the ultrasonic mounting machine, in a direction (direction C) in which the sub-mount 20 has been mechanically fixed by using the jigs 300a and 300b, whereby the optical semiconductor element 10 and the Au bumps 50 are joined to each other by the ultrasonic wave.

Since joining by an ultrasonic wave is thus performed after the temperatures of the Au bumps 50 are increased so as to become approximately equal to the temperature of the optical semiconductor element 10, favorable joining can be performed even at a lower load and a lower amplitude and in a shorter time than in the case of joining at normal temperature. Therefore, the optical semiconductor element 10 can be inhibited from being broken owing to the ultrasonic wave applied at the time of joining. In addition, thermal stress to be applied to the joining portions of the Au bumps 50 when the optical semiconductor element 10, the sub-mount 20, and the insulating substrate 30 which have been completely assembled are detached from the stage 300 of the ultrasonic mounting machine and cooled, can be made smaller than that in a case where the Au bumps 50 are joined at normal temperature without being heated, whereby the optical module 1001 can be inhibited from being broken owing to peeling of the joining portions of the Au bumps 50 due to heating and cooling performed after flip chip bonding. In addition, since the optical semiconductor element 10 is die-bonded to the sub-mount 20 in a step before flip chip bonding, the optical semiconductor element 10 does not need to be mechanically fixed directly at the time of flip chip bonding, whereby the element can be prevented from being broken as a result of coming into contact with a fixation jig or the like at the time of flip chip bonding.

In the present embodiment 3, after the optical semiconductor element 10 is die-bonded to the sub-mount 20, the sub-mount 20 is placed on the stage of the ultrasonic mounting machine and fixed, and, in this state, the insulating substrate 30 is flip-chip-bonded. However, the order of assembling of the optical semiconductor element 10, the sub-mount 20, and the insulating substrate 30 is not limited thereto. For example, assembling may be performed in the following order. That is, the optical semiconductor element 10 is placed on the stage of the ultrasonic mounting machine and directly fixed, the insulating substrate 30 is flip-chip-bonded, and then the optical semiconductor element 10 to which the insulating substrate 30 has been flip-chip-bonded is die-bonded to the sub-mount 20. However, in the case where side surfaces or the like of the optical semiconductor element 10 are mechanically fixed by using jigs or the like, vibration due to an ultrasonic wave to be applied at the time of flip chip bonding and the orientation of the fixation with the jigs need to be set so as not to allow the jigs to touch the laser light generation units of the optical semiconductor element 10 such that the laser light generation units of the optical semiconductor element 10 are not broken owing to the vibration due to the ultrasonic wave. For example, in a case where the laser light generation units are formed on the side surfaces on the short sides of the optical semiconductor element 10, in a state where both side surfaces on the long sides of the optical semiconductor element 10 are fixed by using the jigs, the insulating substrate 30 needs to be flip-chip-bonded so as to vibrate with respect to the long sides of the optical semiconductor element 10 fixed by using the jigs.

In the case where the insulating substrate 30 is flip-chip-bonded before the optical semiconductor element 10 is die-bonded to the sub-mount 20, the joining portions of the Au bumps 50 receive thermal stress generated through heating at the time of die-bonding to the sub-mount 20 and cooling. However, in the case where the insulating substrate 30 is flip-chip-bonded before the optical semiconductor element 10 is die-bonded to the sub-mount 20, it is possible to eliminate influence of the optical semiconductor element 10 being tilted owing to unevenness in the thickness of the AuSn solder 70 pre-coating the sub-mount 20, or being warped owing to thermal stress applied at the time of die-bonding. Consequently, an ultrasonic wave can be inhibited from being applied in a state where only a specific one of the Au bumps 50 is in contact with the optical semiconductor element 10. Thus, after flip chip bonding during which the insulating substrate 30 is rotated, the specific Au bump 50 can be inhibited from being excessively deformed owing to the application of the ultrasonic wave, whereby the optical semiconductor element 10 can be inhibited from being broken owing to the excessive deformation.

As described above, the method for producing the optical module 1001 according to the present embodiment 3 includes: a step of providing an Au bump 50 onto a surface of an electrode pad 10b formed on a front surface of an optical semiconductor element 10 or a surface of an electrode pad 30b formed on a back surface of an insulating substrate 30, and placing the insulating substrate 30 over the optical semiconductor element 10 at such a position that the electrode pad 10b of the optical semiconductor element 10 and the electrode pad 30b of the insulating substrate 30 face each other; a step of heating the Au bump 50 in a state where the insulating substrate 30 is placed over the optical semiconductor element 10; and a step of joining, by an ultrasonic wave, the Au bump 50 and the electrode pad 30b of the insulating substrate 30 or the electrode pad 10b of the optical semiconductor element 10 while pressing the Au bump 50 and the electrode pad 30b or the electrode pad 10b. Consequently, a favorable joined state can be obtained at a lower load and a lower amplitude and in a shorter time than in the case of joining at normal temperature. Therefore, the optical semiconductor element can be inhibited from being broken owing to a load and an amplitude applied at the time of the joining by the ultrasonic wave. In addition, stress to be applied to the joining portion of the Au bump when the optical semiconductor element, the sub-mount, and the insulating substrate which have been completely assembled are detached from the stage of the ultrasonic mounting machine and cooled, can be made smaller than that in a case where the optical semiconductor element and the Au bump are joined to each other in a state where there is a difference in temperature therebetween. Consequently, the joining portion of the Au bump can be inhibited from peeling through heating and cooling performed after flip chip bonding, whereby the optical module can be inhibited from being broken owing to the peeling. Therefore, an optical module that has a higher yield and higher reliability can be obtained.

### Embodiment 4

In embodiment 4, a method for producing the optical semiconductor element 10, the sub-mount 20, and each of the insulating substrates 30 of the optical module 1001 according to embodiment 2 will be described.

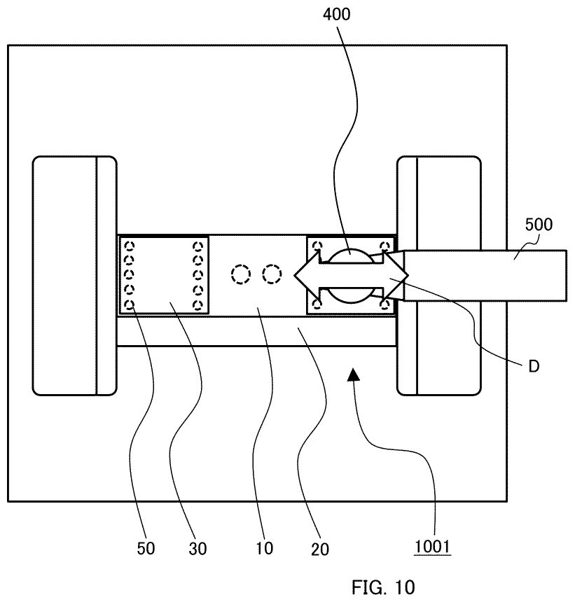

FIG. 10 is a top view showing the method for producing the optical module according to embodiment 4. The method for producing the optical module 1001 according to the present embodiment 4 has the same basic production steps as those of the method for producing the optical module 1001 according to embodiment 3, but differs in a flip chip bonding step (shown in FIG. 10) for the insulating substrate 30. Therefore, here, the difference will be mainly described, and description of the same production steps will be omitted. FIG. 10 shows only a method for flip chip bonding, by using the ultrasonic mounting machine, the insulating substrate 30 to the optical semiconductor element 10 die-bonded to the sub-mount 20 in the optical module 1001 and does not show or explain the other assembling steps.

In embodiment 3, the Au bumps 50 are evenly arranged within the surface of the insulating substrate 30, and thus vibration due to an ultrasonic wave applied to the arranged Au bumps 50 at the time of flip chip bonding poses no problem regardless of the direction of the vibration due to the ultrasonic wave. Meanwhile, the present embodiment 4 differs from embodiment 3 in that a configuration in which the Au bumps 50 on each of both end sides of the insulating substrate 30 are arranged in a concentrated manner in one row is employed, and thus vibration due to an ultrasonic wave is applied in a direction perpendicular to each row of the Au bumps 50.

In the optical module 1001 according to the present embodiment 4, the Au bumps 50 on each of both end sides of the insulating substrate 30 are arranged in one row. Therefore, it is likely that, when an ultrasonic wave is applied in the same direction as the direction of each row of the Au bumps 50, the Au bumps 50 located at both ends of the row are joined first so that vibration due to the ultrasonic wave is suppressed, whereby the joining performances of the Au bumps 50 located on the inner side of the row decrease. This decrease raises a concern that application of stress to the joining portions of the Au bumps 50 leads to peeling of the joining portion of the Au bump 50 that is located at the center of the row and that has a lower joining performance than the Au bumps 50 at both ends of the row, whereby the optical module 1001 is broken.

Considering this, the present embodiment 4 employs, as a method for obtaining equally favorable joining performances of the Au bumps 50 arranged in one row on each of both end sides of the insulating substrate 30 so that the reliability required of the product is ensured in a state where the size of the optical semiconductor element 10 is decreased, a method that includes applying an ultrasonic wave in a direction (direction D) perpendicular to each row of the arranged Au bumps 50 as shown in FIG. 10. With this method, all of the arranged Au bumps 50 are located at both ends in the direction of vibration due to the ultrasonic wave. Consequently, a specific one of the Au bumps 50 can be inhibited from being joined first, whereby the joining performances of the other Au bumps 50 can be inhibited from decreasing owing to the joining. Thus, as compared to a case where an ultrasonic wave is applied in the same direction as the direction of each row of the Au bumps 50, the reliability of the product can be improved since the optical module 1001 is inhibited from being broken owing to peeling of the joining portions of the Au bumps 50.

In embodiment 3, the order of assembling of the optical semiconductor element 10, the sub-mount 20, and the insulating substrate 30 may be such that, after the insulating substrate 30 is flip-chip-bonded to the optical semiconductor element 10, the optical semiconductor element 10 to which the insulating substrate 30 has been flip-chip-bonded is die-bonded to the sub-mount 20. However, in the present embodiment 4, the order of assembling of the optical semiconductor element 10, the sub-mount 20, and the insulating substrate 30 is preferably such that, after the optical semiconductor element 10 is die-bonded to the sub-mount 20, the sub-mount 20 is placed on the stage of the ultrasonic mounting machine and fixed, and, in this state, the insulating substrate 30 is flip-chip-bonded.

The reason is as follows. In a case where, for example, side surfaces of the optical semiconductor element 10 are mechanically fixed by using jigs or the like, side surfaces thereof on both sides in the direction of application of vibration due to an ultrasonic wave need to be mechanically sandwiched such that the optical semiconductor element 10 is fixed so as not to move in the direction of vibration due to an ultrasonic wave. Then, vibration due to an ultrasonic wave is applied in the direction in which the optical semiconductor element 10 has been mechanically fixed (in the present embodiment 4, the direction perpendicular to each row of the arranged Au bumps 50), whereby the optical semiconductor element 10 and the Au bumps 50 are joined to each other by the ultrasonic wave. In this case, as described in embodiment 2, the optical semiconductor element 10 on which the plurality of laser light generation units have been formed is preferably such that the electrode pads 10b formed on the optical semiconductor element 10 are arrayed in one row with respect to each of the laser light generation units, and one of the rows of the Au bumps 50 arranged on the insulating substrate 30 is located at a position that enables joining to the electrode pads 10b. Thus, the plurality of laser light generation units are preferably formed on side surfaces, of the optical semiconductor element 10, in the direction perpendicular to the row of the arranged electrode pads 10b, i.e., the row of the arranged Au bumps 50.

Therefore, in the case where the insulating substrate 30 is flip-chip-bonded before the optical semiconductor element 10 is die-bonded to the sub-mount 20, the method for producing the optical module according to the present embodiment 4 makes it necessary for the side surfaces, on which the laser light generation units have been formed, of the optical semiconductor element 10 to be sandwiched and fixed by using jigs or the like at the time of flip chip bonding and raises a concern that the laser light generation units of the optical semiconductor element 10 are broken owing to vibration due to an ultrasonic wave applied at the time of the flip chip bonding.

For the above reason, the present embodiment 4 is preferably as follows. That is, after the optical semiconductor element 10 is die-bonded to the sub-mount 20, the sub-mount 20 is placed on the stage of the ultrasonic mounting machine, the side surfaces of the sub-mount 20 in the direction in which the laser light generation units of the optical semiconductor element 10 have been formed are mechanically fixed by using jigs, and in this state, vibration due to an ultrasonic wave is applied in the direction in which the sub-mount 20 has been mechanically fixed, such that the optical semiconductor element 10 and the Au bumps 50 are joined to each other by the ultrasonic wave to flip-chip-bond the insulating substrate 30.

As described above, the method for producing the optical module 1001 according to the present embodiment 4 includes: a step of providing an Au bump 50 onto a surface of an electrode pad 10b formed on a front surface of an optical semiconductor element 10 or a surface of an electrode pad 30b formed on a back surface of an insulating substrate 30, and placing the insulating substrate 30 over the optical semiconductor element 10 at such a position that the electrode pad 10b of the optical semiconductor element 10 and the electrode pad 30b of the insulating substrate 30 face each other; a step of heating the Au bump 50 in a state where the insulating substrate 30 is placed over the optical semiconductor element 10; and a step of joining, by an ultrasonic wave, the Au bump 50 and the electrode pad 30b of the insulating substrate 30 or the electrode pad 10b of the optical semiconductor element 10 while pressing the Au bump 50 and the electrode pad 30b or the electrode pad 10b. This method includes locating the Au bump 50 at each of a position close to one end of the insulating substrate and a position close to another end, of the insulating substrate, opposite to the one end, and the joining by the ultrasonic wave includes applying vibration due to the ultrasonic wave in a direction perpendicular to the one end of the insulating substrate 30. Consequently, the following advantageous effects are obtained at a lower load and a lower amplitude and in a shorter time than in the case of joining at normal temperature. That is, a specific one of the Au bumps is inhibited from being joined first, whereby the joining performances of the other Au bumps are inhibited from decreasing owing to the joining. Thus, all of the arranged Au bumps can enter favorable joined states. Therefore, the optical semiconductor element can be inhibited from being broken owing to a load and an amplitude applied at the time of the joining by the ultrasonic wave. In addition, the following advantageous effect of the optical module according to embodiment 3 can be obtained. That is, thermal stress to be applied to the joining portion of each of the Au bumps through heating and cooling can be made smaller than that in a case where the optical semiconductor element and the Au bump are joined to each other in a state where there is a difference in temperature therebetween. Consequently, the joining portion of the Au bump can be inhibited from peeling after flip chip bonding, whereby the optical module can be inhibited from being broken owing to the peeling. Furthermore, the following advantageous effect of embodiment 2 can also be obtained. That is, the number of the Au bumps necessary for ensuring the reliability of the product can be decreased. Consequently, any of the electrode pads on the front surface of the insulating substrate can be inhibited from, owing to friction with the tip of an attraction collet caused by vibration due to an ultrasonic wave, being deformed so as to come into contact with an adjacent one of the electrode pads, whereby short-circuiting due to the contact can be inhibited. In addition, the number of the dummy electrode pads that are formed on the optical semiconductor element and that are for merely mechanically fixing the insulating substrate can be decreased. Accordingly, the size of the optical semiconductor element can be decreased. Therefore, an optical module that is less expensive and that has a higher yield and higher reliability can be obtained.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure. It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### Description of the Reference Characters

10 optical semiconductor element
10b electrode pad
30 insulating substrate
30b, 30c electrode pad
30d through-hole
50 Au bump
1001 optical module

1. An optical module comprising:
a semiconductor element made from InP and having a front surface on which an electrode pad is formed;
an insulating substrate having a front surface and a back surface on which respective electrode pads are formed; and
a bump with which the electrode pad on the back surface of the insulating substrate and the electrode pad of the semiconductor element are joined to each other, wherein
the insulating substrate is disposed such that the back surface thereof faces the front surface of the semiconductor element, and
the electrode pad on the back surface of the insulating substrate is connected via a through-hole to the electrode pad on the front surface of the insulating substrate.

2. The optical module according to claim 1, wherein
an area of each surface, of the insulating substrate, on which the corresponding electrode pad is formed is smaller than an area of the surface, of the semiconductor element, on which the electrode pad is formed.

3. The optical module according to claim 1, wherein
the bumps are evenly arranged within a surface of the insulating substrate.

4. The optical module according to claim 1, wherein
the bump is located at each of an edge portion of one end, of the insulating substrate, on a side on which connection to outside is made and an edge portion of another end, of the insulating substrate, opposite to the one end.

5. The optical module according to claim 4, wherein
the bump located at the edge portion of the other end is a dummy.

6. The optical module according to claim 4, wherein
the semiconductor element includes a laser light generation unit, and
the laser light generation unit is provided to a side surface, of the semiconductor element, in a direction perpendicular to the one end.

7. A method for producing an optical module, the method comprising:
a step of providing a bump onto a surface of an electrode pad formed on a front surface of a semiconductor element made from InP or a surface of an electrode pad formed on a back surface of an insulating substrate, and placing the insulating substrate over the semiconductor element at such a position that the electrode pad of the semiconductor element and the electrode pad of the insulating substrate face each other;
a step of heating the bump in a state where the insulating substrate is placed over the semiconductor element; and
a step of joining, by an ultrasonic wave, the bump and the electrode pad of the insulating substrate or the electrode pad of the semiconductor element while pressing the bump and the electrode pad.

8. The method for producing an optical module, according to claim 7, the method comprising:
disposing the insulating substrate such that the back surface thereof faces the front surface of the semiconductor element; and
connecting the electrode pad on the back surface of the insulating substrate via a through-hole to an electrode pad on a front surface of the insulating substrate.

9. The method for producing an optical module, according to claim 7, wherein
an area of the surface, of the insulating substrate, on which the electrode pad is formed is smaller than an area of the surface, of the semiconductor element, on which the electrode pad is formed.

10. The method for producing an optical module, according to claim 7, the method comprising
evenly arranging the bumps within a surface of the insulating substrate.

11. The method for producing an optical module, according to claim 7, the method comprising
locating the bump at each of an edge portion of one end, of the insulating substrate, on a side on which connection to outside is made and an edge portion of another end, of the insulating substrate, opposite to the one end.

12. The method for producing an optical module, according to claim 11, wherein
the bump located at the edge portion of the other end is a dummy.

13. The method for producing an optical module, according to claim 11, wherein
the joining by the ultrasonic wave includes applying vibration due to the ultrasonic wave in a direction perpendicular to the one end.

14. The method for producing an optical module, according to claim 11, wherein
the semiconductor element includes a laser light generation unit, and
the laser light generation unit is provided to a side surface, of the semiconductor element, in a direction perpendicular to the one end.

15. The optical module according to claim 1, wherein
the semiconductor element is joined via a solder to a front surface of a sub-mount.
